(19) United States
(12) Patent Application Publication
(10) Pub. No.: US 2013/0074932 A1
(43) Pub. Date: Mar. 28, 2013

(54) SOLAR CELL PACKAGE STRUCTURE

(71) Applicants: Chj-Don TENG, Taipei City (TW); Wei-Lun Hsu, Taipei City (TW)

(72) Inventors: Chj-Don TENG, Taipei City (TW); Wei-Lun Hsu, Taipei City (TW)

(21) Appl. No.: 13/346,522

(22) Filed: Jan. 9, 2012

(30) Foreign Application Priority Data
Sep. 23, 2011 (TW) 100134420

(51) Int. Cl. H01L 31/0203

(52) U.S. Cl. 136/259

(57) ABSTRACT

A solar cell package structure includes a first substrate, a second substrate and a sealant. The first substrate has a first surface with a first rough portion. The second substrate has a second surface with a second rough portion, which is opposite to the first surface. The sealant is disposed between the first and second substrates and bonds the first and second surfaces. At least a part of the sealant covers the first rough portion and the second rough portion.

### CROSS REFERENCE TO RELATED APPLICATIONS

This Non-provisional application claims priority under 35 U.S.C. §119(a) on Patent Application No(s). 100134420 filed in Taiwan, Republic of China on Sep. 23, 2011, the entire contents of which are hereby incorporated by reference.

### BACKGROUND OF THE INVENTION

1. Field of Invention

The present invention relates to a package structure and, in particular, to a solar cell package structure.

2. Related Art

Solar energy usually does not cause the environmental pollution and is easily to be retrieved, so that it has become one of the substituted energy sources. In general, the solar cell, which is a photoelectric conversion element, is used to absorb the solar light and convert the solar energy into electricity.

The common solar cells include silicon-based solar cells, compound semiconductor solar cells, organic solar cells, and dye sensitized solar cells (DSSC). Except for the material of the solar cell, the reliability of the package structure of the solar cell is also a very important factor for affecting the photoelectric conversion efficiency of the solar cell. If the package structure of the solar cell is not sealed airtightly, moisture and dusts may enter the package structure, thereby decreasing the performance and lifetime of the solar cell. Besides, the package structure of the DSSC usually contains electrolyte. If the package structure is not reliable, the electrolyte therein may leak out so as to damage the solar cell and decrease the production yield.

Therefore, it is an important subject of the present invention to provide a solar cell package structure that can improve the sealing degree of the package, thereby increasing the reliability and performance of the product.

### SUMMARY OF THE INVENTION

In view of the foregoing subject, an object of the present invention is to provide a solar cell package structure that can improve the sealing degree of the package, thereby increasing the reliability and performance of the product.

To achieve the above object, the present invention discloses a solar cell package structure including a first substrate, a second substrate and a sealant. The first substrate has a first surface with a first rough portion. The second substrate has a second surface with a second rough portion, which is opposite to the first surface. The sealant is disposed between the first and second substrates and bonds the first and second surfaces. At least a part of the sealant covers the first rough portion and the second rough portion.

In one embodiment, the solar cell package structure is applied to a silicon-based solar cell, a compound semiconductor solar cell, or an organic solar cell.

In one embodiment, the solar cell package structure is applied to a dye sensitized solar cell.

In one embodiment, the surface roughness of the first rough portion is greater than 0.1 μm.

In one embodiment, the surface roughness of the second rough portion is greater than 0.1 μm.

In one embodiment, the sealant, the first substrate and the second substrate form a sealed space.

In one embodiment, the first rough portion and the second rough portion are aligned or misaligned with each other.

In one embodiment, the areas of the first rough portion and the second rough portion are equal or non-equal to each other.

In one embodiment, the first rough portion or the second rough portion is a continuous or discontinuous structure.

In one embodiment, the first rough portion or the second rough portion is formed by laser ablation, mechanical processing, chemical reaction, or semiconductor process.

In one embodiment, the first rough portion or the second rough portion comprises a groove, and the cross-section of the groove is in a U shape, a V shape, a sawtooth shape, or a rectangle.

In one embodiment, the first rough portion or the second rough portion comprises a pattern.

As mentioned above, in the solar cell package structure of the present invention, the sealant is connected with the first and second substrates, and the first and second substrates have rough portions for contacting with the sealant. The configuration of the rough portions can increase the contact areas between the sealant and the first and second substrates, thereby strengthening the connecting strength between the sealant and the first and second substrates. Accordingly, the sealing degree of the solar cell package structure can be improved, so that the reliability and performance of the product can be enhanced.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a solar cell package structure according to a first embodiment of the present invention;

FIG. 2 to FIG. 6 are schematic diagrams showing various aspects of the first and second rough portions of the present invention; and

FIG. 7 is a schematic diagram showing a solar cell package structure according to a second embodiment of the present invention.

### DETAILED DESCRIPTION OF THE INVENTION

The present invention will be apparent from the following detailed description, which proceeds with reference to the accompanying drawings, wherein the same references relate to the same elements.

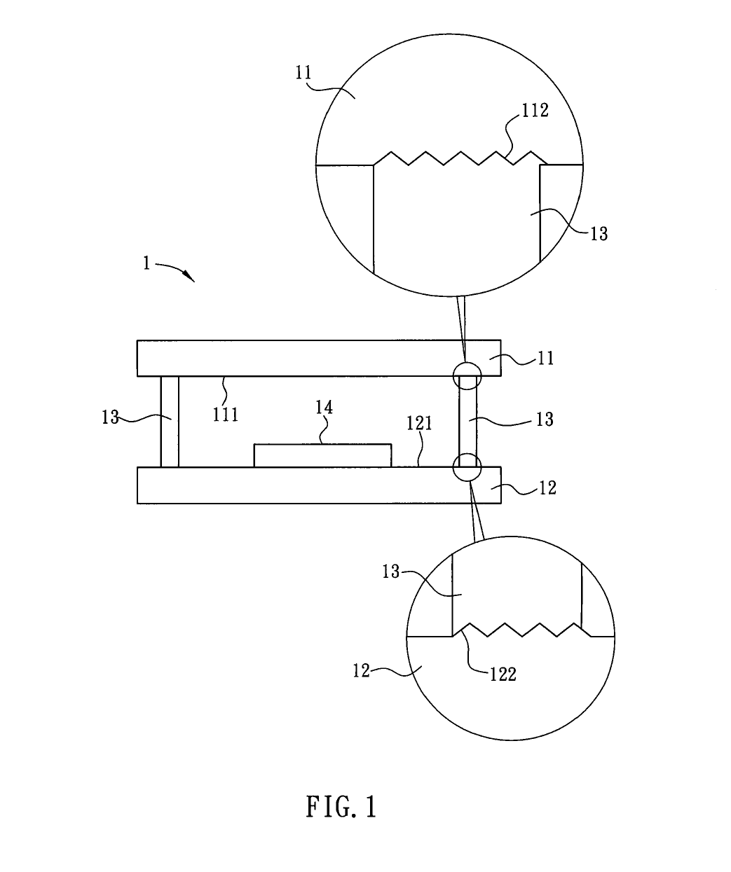

FIG. 1 is a schematic diagram showing a solar cell package structure 1 according to a first embodiment of the present invention. The solar cell package structure 1 includes a first substrate 11, a second substrate 12, and a sealant 13. Besides, the solar cell package structure 1 further includes a solar cell component 14, which is disposed on the first substrate 11 or the second substrate 12. In this embodiment, the solar cell component 14 is disposed on the second substrate 12. The solar cell component 14 of the solar cell package structure 1 can be, for example but not limited to, a silicon-based solar cell component, a compound semiconductor solar cell component, an organic solar cell component, or a dye sensitized solar cell component. In this embodiment, the solar cell component 14 is a compound semiconductor solar cell component such as a CIGS (Copper, Indium, Gallium, Selenium) solar cell component.

The material of the first substrate 11 is, for example but not limited to, a silicon substrate, a ceramic substrate, a metal substrate, a glass substrate, a polymer film or a plastic substrate. The first substrate 11 has a first surface 111 with a first rough portion 112 (see the enlarged portion in FIG. 1). The roughness (Ra) of the first rough portion 112 is larger than 0.1 μm. Due to the configuration of the rough portion 112 on the first surface 111, the contact area between the sealant 13 and the rough portion 112 of the first surface 111 can be increased, thereby strengthening the connection strength between the sealant 13 and the first substrate 11. In this embodiment, the first rough portion 112 can be formed by laser ablation, mechanical processing (e.g. milling machine, grinding wheel, or CNC processing), chemical reaction, or semiconductor process. In practice, any process or method that can increase the roughness of the first surface 111 is applicable. The first rough portion 112 includes a groove with a V-shaped cross-section. Of course, the cross-section of the groove can be in a U shape or rectangle.

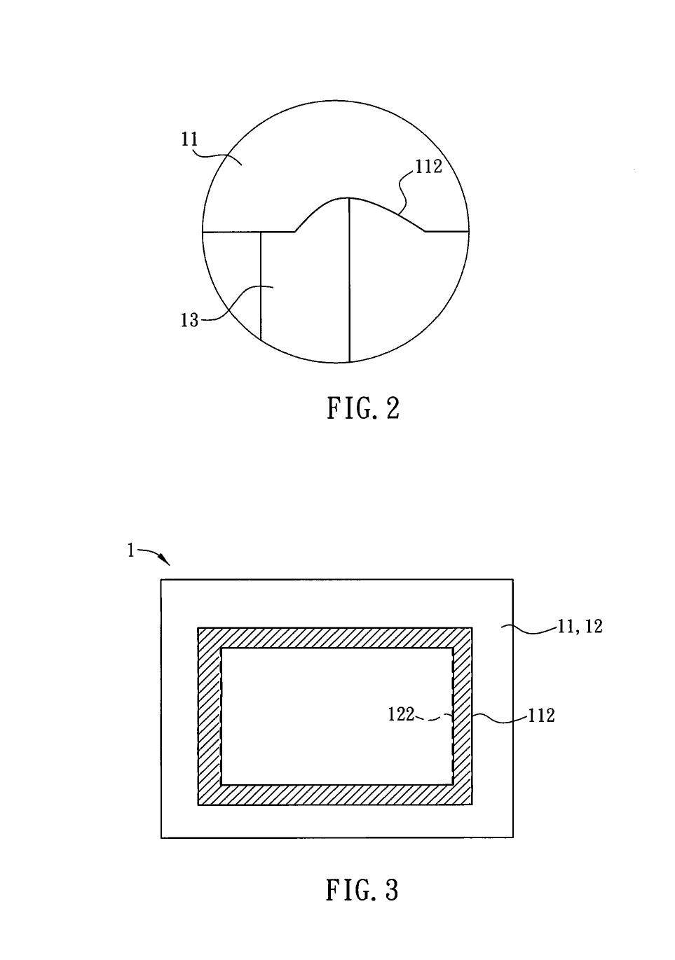

Alternatively, the first rough portion 112 may include other pattern. For example, the cross-section of the first rough portion 112 is U-shaped (see FIG. 2). When disposing the sealant 13, a part of the sealant 13 flows into the first rough portion 112. This configuration can prevent the overflow of the sealant 13, and increase the bonding strength between the sealant 13 and the first rough portion 112. Besides, the cross-section of the groove may be in different shape, such as a V shape, a rectangle, or a sawtooth shape. Similarly, the above-mentioned features of the first rough portion 112 can also fit to the second rough portion 122, so the detailed descriptions thereof are omitted.

The material of the second substrate 12 is, for example but not limited to, a silicon substrate, a ceramic substrate, a metal substrate, a glass substrate, a polymer film or a plastic substrate. The second substrate 12 has a second surface 121 with a second rough portion 122 (see the enlarged portion in FIG. 1). The roughness (Ra) of the second rough portion 122 is larger than 0.1 μm. Due to the configuration of the rough portion 122 on the second surface 121, the contact area between the sealant 13 and the rough portion 122 of the first surface 121 can be increased, thereby strengthening the connection strength between the sealant 13 and the second substrate 12. In this embodiment, the second rough portion 122 can be formed by laser ablation, mechanical processing (e.g. milling machine, grinding wheel, or CNC processing), chemical reaction, or semiconductor process. In practice, any process or method that can increase the roughness of the second surface 121 is applicable. The second rough portion 122 includes a groove with a V-shaped cross-section. Of course, the cross-section of the groove can be in a U shape, rectangle, sawtooth shape, or any other applicable pattern.

The sealant 13 is disposed between the first substrate 11 and the second substrate 12 for bonding the first surface 111 and the second surface 121. At least a part of the sealant 13 covers the first rough portion 112 and the second rough portion 122. In other words, at least a part of the sealant 13 is connected with the first rough portion 112 and the second rough portion 122. The first substrate 11, the second substrate 12, and the sealant 13 can form an airtight sealed space for protecting the internal solar cell component. The sealant 13 may include the material with water-proof, thermal resisting, and anti-corrosion properties for extending the lifetime of the product.

In the present invention, the first rough portion 112 and the second rough portion 122 may have various aspects, which will be described hereinafter. To make the following description simpler, the reference figures show the projection of the first rough portion 112 and the second rough portion 122 after the first substrate 11 and the second substrate 12 are aligned. Herein, the first rough portion 112 is shown by solid lines, and the second rough portion 122 is shown by dotted lines.

As shown in FIG. 3, the first rough portion 112 and the second rough portion 122 of the solar cell package structure 1 are exactly overlapped. That is, the first rough portion 112 and the second rough portion 122 are aligned to each other. Besides, the first rough portion 112 and the second rough portion 122 are continuous rectangular borders, and their areas are equal to each other.

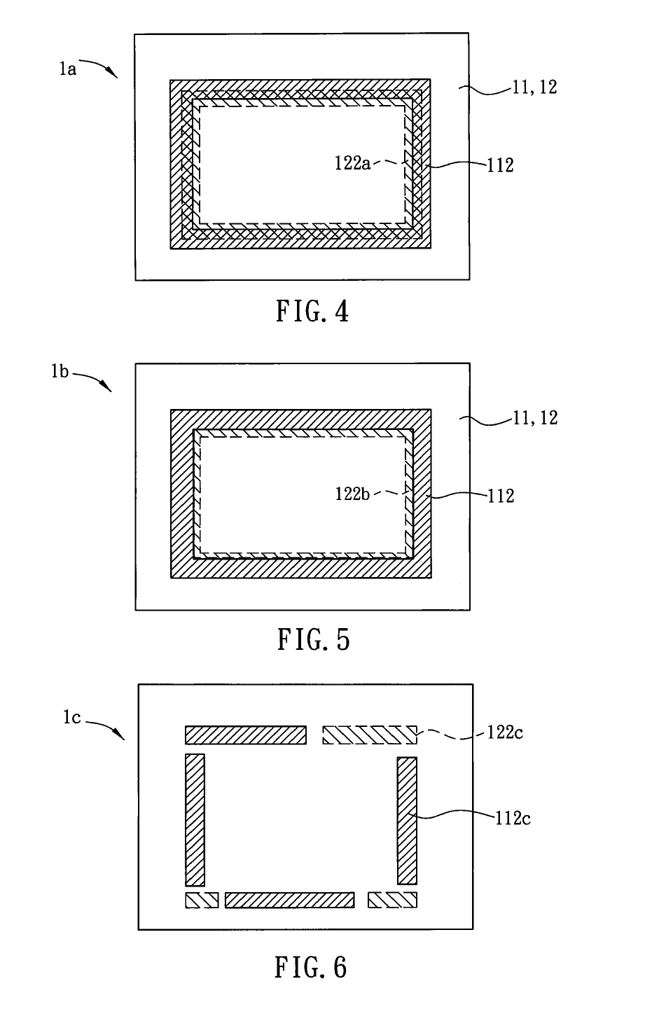

As shown in FIG. 4, in the solar cell package structure 1a, the area of the first rough portion 112 is larger than that of the second rough portion 122a, and the first rough portion 112 and the second rough portion 122a are partially overlapped.

As shown in FIG. 5, in the solar cell package structure 1b, the area of the first rough portion 112 is larger than that of the second rough portion 122b, and the first rough portion 112 and the second rough portion 122b are not overlapped. The width of the second rough portion 122b is smaller than that of the first rough portion 112.

As shown in FIG. 6, the first rough portion 112c and the second rough portion 122c of the solar cell package structure 1c are misaligned, and they are totally not overlapped. Besides, the first rough portion 112c and the second rough portion 122c are both discontinuous. Of course, the first rough portion 112c of the first substrate 11 can be discontinuous, while the second rough portion 122c of the second substrate 12 is continuous. Otherwise, the first rough portion 112c can be continuous, while the second rough portion 122c is discontinuous.

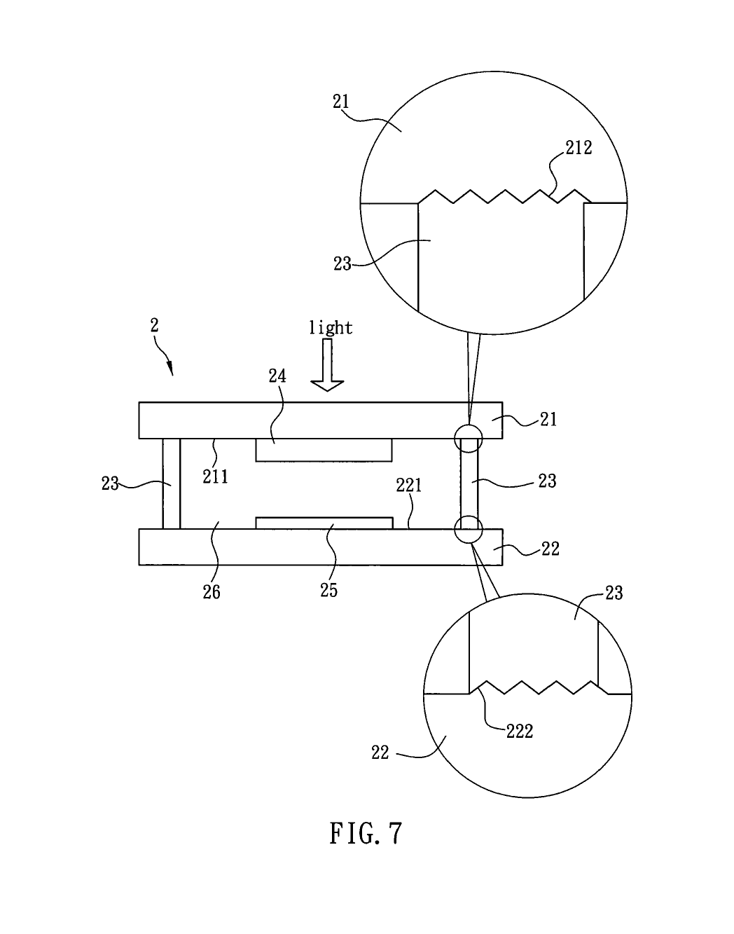

FIG. 7 is a schematic diagram showing a solar cell package structure 2 according to a second embodiment of the present invention. In this embodiment, the solar cell package structure 2 comprises a dye sensitized solar cell component for example. The solar cell package structure 2 includes a first substrate 21, a second substrate 22, and a sealant 23.

The material of the first substrate 21 is, for example but not limited to, a silicon substrate, a ceramic substrate, a metal substrate, a glass substrate, a polymer film or a plastic substrate. In this embodiment, the first substrate 21 is a light-permeable substrate. The first substrate 21 has a first surface 211 with a first rough portion 212 (see the enlarged portion in FIG. 7). The features of the first rough portion 212 are the same as those of the first rough portion 112 in the first embodiment, so the detailed description thereof is omitted.

The material of the second substrate 22 is, for example but not limited to, a silicon substrate, a ceramic substrate, a metal substrate, a glass substrate, a polymer film or a plastic substrate. In this embodiment, the second substrate 22 is a light-permeable substrate. The second substrate 22 has a second surface 221 with a second rough portion 222 (see the enlarged portion in FIG. 7). The features of the second rough portion 222 are the same as those of the second rough portion 122 in the first embodiment, so the detailed description thereof is omitted.

The sealant 23 is disposed between the first substrate 21 and the second substrate 22 for bonding the first surface 211 and the second surface 221. At least a part of the sealant 23 covers the first rough portion 212 and the second rough portion 222. In other words, at least a part of the sealant 23 is connected with the first rough portion 212 and the second rough portion 222. The first substrate 21, the second substrate 22, and the sealant 23 can form an airtight sealed space for protecting the internal solar cell component. The sealant 23 may include the material with water-proof, thermal resisting, and anti-corrosion properties for extending the lifetime of the product.

In this embodiment, the solar cell package structure 2 further includes a first electrode 24, a second electrode 25, and an electrolyte 26. The first electrode 24 is formed on the first substrate 21 and includes a patterned conductive layer, a porous nano-structure, and a dye. For example, the patterned conductive layer is made of transparent conductive oxide, and the porous nano-structure includes TiO₂ nano-particles. The second electrode 25 is formed on the second surface 221 of the second substrate 22 and includes a patterned conductive layer. In particular, the second electrode 25 may further include a catalyst layer, which is made of platinum for example. The electrolyte 26 is filled within the sealant 23. In this case, the electrolyte 26 may include metal-complex pigments containing ruthenium, or organic pigment containing methyl or phthalocyanine.

In summary, the sealant of the solar cell package structure is connected with the first and second substrates, while the first and second substrates have rough portions for contacting with the sealant. The configuration of the rough portions can increase the contact areas between the sealant and the first and second substrates, thereby strengthening the connecting strength between the sealant and the first and second substrates. Accordingly, the sealing degree of the solar cell package structure can be improved, so that the reliability and performance of the product can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A solar cell package structure, comprising:
a first substrate having a first surface with a first rough portion;
a second substrate having a second surface with a second rough portion, wherein the second surface is disposed opposite to the first surface; and
a sealant disposed between the first substrate and the second substrate and bonding the first surface and the second surface, wherein at least a part of the sealant covers the first rough portion and the second rough portion.

2. The solar cell package structure according to claim 1, wherein the solar cell package structure is applied to a silicon-based solar cell, a compound semiconductor solar cell, or an organic solar cell.

3. The solar cell package structure according to claim 1, wherein the solar cell package structure is applied to a dye sensitized solar cell.

4. The solar cell package structure according to claim 1, wherein the surface roughness of the first rough portion is greater than 0.1 μm.

5. The solar cell package structure according to claim 1, wherein the surface roughness of the second rough portion is greater than 0.1 μm.

6. The solar cell package structure according to claim 1, wherein the sealant, the first substrate and the second substrate form a sealed space.

7. The solar cell package structure according to claim 1, wherein the first rough portion and the second rough portion are aligned or misaligned with each other.

8. The solar cell package structure according to claim 1, wherein the areas of the first rough portion and the second rough portion are equal or non-equal to each other.

9. The solar cell package structure according to claim 1, wherein the first rough portion or the second rough portion is a continuous or discontinuous structure.

10. The solar cell package structure according to claim 1, wherein the first rough portion or the second rough portion is formed by laser ablation, mechanical processing, chemical reaction, or semiconductor process.

11. The solar cell package structure according to claim 1, wherein the first rough portion or the second rough portion comprises a groove.

12. The solar cell package structure according to claim 1, wherein the first rough portion or the second rough portion comprises a pattern.
